(19) United States
(12) Patent Application Publication
(10) Pub. No.: US 2024/0429062 A1
(43) Pub. Date: Dec. 26, 2024

(54) INCREASED ETCH RATES OF SILICON-CONTAINING MATERIALS

(71) Applicant: Applied Materials, Inc., Santa Clara, CA (US)

(72) Inventors: Alok Ranjan, San Ramon, CA (US); Anatoli Chlenov, San Jose, CA (US); Kenji Takeshita, Sunnyvale, CA (US)

(73) Assignee: Applied Materials, Inc., Santa Clara, CA (US)

(21) Appl. No.: 18/212,314

(22) Filed: Jun. 21, 2023

(51) Int. Cl. H01L 21/311; H01J 37/32

(52) U.S. Cl. CPC H01L 21/31116; H01J 37/32816; H01J 37/32853; H01J 2237/182; H01J 2237/334

(57) ABSTRACT

Exemplary methods of semiconductor processing may include providing a hydrogen-containing precursor and a fluorine-containing precursor to a processing region of a semiconductor processing chamber. A substrate may be disposed on a substrate support within the processing region. One or more layers of silicon-containing material may be disposed on the substrate. The methods may include forming plasma effluents of the hydrogen-containing precursor and the fluorine-containing precursor. The methods may include contacting one or more layers of silicon-containing material with plasma effluents of the hydrogen-containing precursor and the fluorine-containing precursor. The contacting may etch a portion of the one or more layers of silicon-containing material.

### TECHNICAL FIELD

The present technology relates to semiconductor processes and equipment. More specifically, the present technology relates to etching operations of silicon-containing material.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary methods of semiconductor processing may include providing a hydrogen-containing precursor and a fluorine-containing precursor to a processing region of a semiconductor processing chamber. A substrate may be disposed on a substrate support within the processing region. One or more layers of silicon-containing material may be disposed on the substrate. The methods may include forming plasma effluents of the hydrogen-containing precursor and the fluorine-containing precursor. The methods may include contacting one or more layers of silicon-containing material with plasma effluents of the hydrogen-containing precursor and the fluorine-containing precursor. The contacting may etch a portion of the one or more layers of silicon-containing material.

In some embodiments, the hydrogen-containing precursor may be or include diatomic hydrogen (H₂). The fluorine-containing precursor may be or include hydrogen fluoride (HF) or nitrogen trifluoride (NF₃). The one or more layers of silicon-containing material may include alternating layers of silicon-and-oxygen-containing material and silicon-and-nitrogen-containing material. The one or more layers of silicon-containing material may include greater than or about 20 alternating layers of silicon-and-oxygen-containing material and silicon-and-nitrogen-containing material. The methods may include applying a bias power to the substrate support during the contacting. A voltage of the bias power may be greater than or about 500 V. The contacting may etch a feature in the one or more layers of silicon-containing material. The feature may be characterized by an aspect ratio of greater than or about 10:1. The substrate may be characterized by a temperature of less than or about 100° C. The contacting may etch the portion of the one or more layers of silicon-containing material at an etch rate of greater than or about 200 nm/min. The methods may include providing a co-reactant with the hydrogen-containing precursor and the fluorine-containing precursor. The co-reactant may be a boron-containing precursor, a phosphorous-containing precursor, or a sulfur-containing precursor.

Some embodiments on the present technology may encompass semiconductor processing methods. The methods may include providing a hydrogen-containing precursor and a fluorine-containing precursor to a processing region of a semiconductor processing chamber. A substrate may be disposed on a substrate support within the processing region. Alternating layers of silicon-and-oxygen-containing material and silicon-and-nitrogen-containing material may be disposed on the substrate. The methods may include forming plasma effluents of the hydrogen-containing precursor and the fluorine-containing precursor. The methods may include contacting one or more layers of silicon-containing material with plasma effluents of the hydrogen-containing precursor and the fluorine-containing precursor. The contacting may etch a feature through the alternating layers of silicon-and-oxygen-containing material and silicon-and-nitrogen-containing material.

In some embodiments, the contacting may etch the alternating layers of silicon-and-oxygen-containing material and silicon-and-nitrogen-containing material at an etch rate of greater than or about 500 nm/min. A pressure within the semiconductor processing chamber may be maintained at less than or about 150 mTorr. The plasma effluents of the hydrogen-containing precursor and the fluorine-containing precursor may be generated at a plasma power of less than or about 5,000 W.

Some embodiments on the present technology may encompass semiconductor processing methods. The methods may include providing a hydrogen-containing precursor and a fluorine-containing precursor to a processing region of a semiconductor processing chamber. A substrate may be disposed on a substrate support within the processing region. Alternating layers of silicon-and-oxygen-containing material and silicon-and-nitrogen-containing material may be disposed on the substrate. The methods may include providing a co-reactant with the hydrogen-containing precursor and the fluorine-containing precursor. The methods may include forming plasma effluents of the hydrogen-containing precursor, the fluorine-containing precursor, and the co-reactant. The methods may include contacting one or more layers of silicon-containing material with plasma effluents of the hydrogen-containing precursor, the fluorine-containing precursor, and the co-reactant. The contacting may etch a feature through the alternating layers of silicon-and-oxygen-containing material and silicon-and-nitrogen-containing material. The methods may include applying a bias power to the substrate support during the contacting. The bias power draws the plasma effluents of the hydrogen-containing precursor, the fluorine-containing precursor, and the co-reactant to the substrate resulting in an anisotropic etch.

In some embodiments, the co-reactant may be or include a phosphorous-containing precursor. The substrate may be characterized by a temperature of less than or about 0° C.

Such technology may provide numerous benefits over conventional systems and techniques. For example, the processes may increase etch rates of one or more silicon-containing material overlying a substrate. Additionally, the processes may prevent etch rate slowdown, bowing of the feature being etched, bending of the feature being etched, twisting of the feature being etched, clogging, and imbalances between oxide and nitride etch rates. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary processing chamber according to some embodiments of the present technology.

FIG. 3 shows selected operations in an etching method according to some embodiments of the present technology.

FIGS. 4A-4C illustrate cross-sectional views of substrate materials on which selected operations are being performed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include superfluous or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In transitioning from 2D NAND to 3D NAND memory structures, many operations are modified from vertical to horizontal processing. Additionally, as 3D NAND structures grow in the number of cells being formed, the aspect ratios of memory holes and other structures increase, sometimes dramatically. During 3D NAND processing, stacks of placeholder layers and dielectric materials may form the inter-electrode dielectric or inter-poly dielectric (“IPD”) layers. These placeholder layers may have a variety of operations performed to place structures before fully removing the material and replacing it with metal. The IPD layers are often formed overlying a conductor layer. When the memory holes are formed, apertures may extend through all the alternating layers of material before accessing the substrate.

Conventional technologies have typically used a single etchant precursor for etching features through the stacks of layers on the substrate. However, in high aspect ratio structures many challenges are present in these etching operations. For example, as the aspect ratio of the etch increases, etchant species may not as readily reach the etch front and the etch rate may slow down. In some extreme examples, etching may eventually come to a halt at the etch front and/or the feature may become clogged with re-deposited etched byproduct, for example. Accordingly, the etchant species may begin to etch outwards as directionality of the etchant species is reduced. The outward etch may result in bowing, bending, twisting, or other nonuniformity of the etching.

The present technology overcomes these issues by performing an etch processes using a combination of precursors, such as a hydrogen-containing precursor and a fluorine-containing precursor, to increase the etch rate of both the placeholder layers and dielectric materials on the substrate. Additionally, the processing conditions of the present technology, such as the reduced temperature, may result in increased etch rates of the materials on the substrate. Further, a bias power may be applied to maintain directionality of the etchant species within the features being etched. With increased etch rates and increased directionality, the etch rate and uniformity issues associated with conventional technologies may be addressed.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the single-chamber operations described. Similarly, although a specific etching operation will be described, it is to be understood that the processes may be equally applicable to other processes in which etching may be performed. Accordingly, the examples given should not be considered to limit the scope of the described technology.

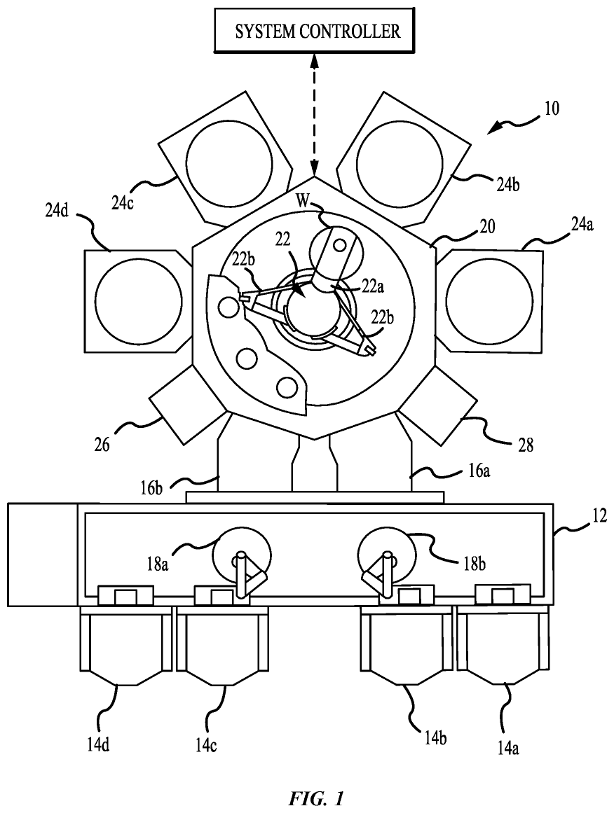

FIG. 1 shows a top plan view of one embodiment of a processing system 10 of deposition, etching, baking, and/or curing chambers according to embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 22b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

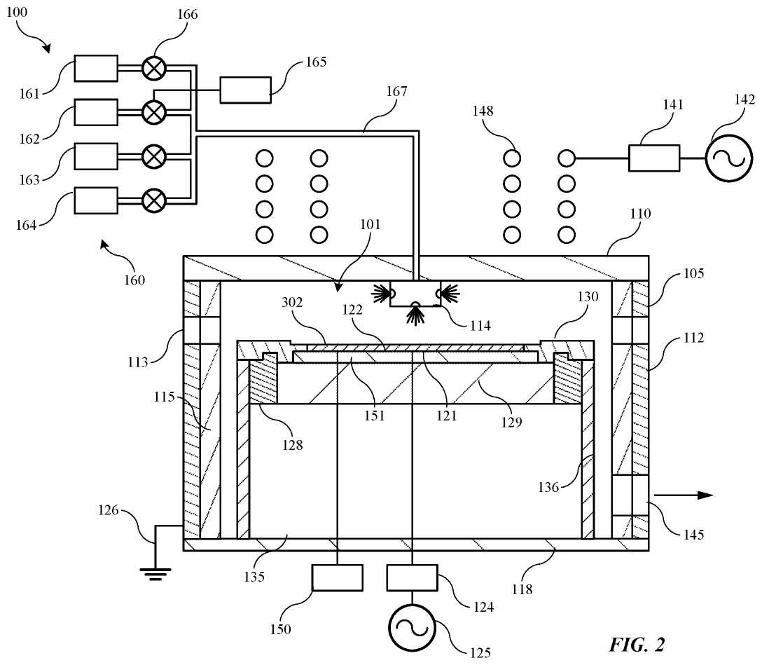

FIG. 2 illustrates a schematic cross-sectional view of an exemplary processing chamber 100 suitable for patterning a material layer disposed on a substrate 302 in the processing chamber 100. The exemplary processing chamber 100 is suitable for performing a patterning process, although it is to be understood that aspects of the present technology may be performed in any number of chambers, and substrate supports according to the present technology may be included in etching chambers, deposition chambers, treatment chambers, or any other processing chamber. The plasma processing chamber 100 may include a chamber body 105 defining a chamber volume 101 in which a substrate may be processed. The chamber body 105 may have sidewalls 112 and a bottom 118 which are coupled with ground 126. The sidewalls 112 may have a liner 115 to protect the sidewalls 112 and extend the time between maintenance cycles of the plasma processing chamber 100. The dimensions of the chamber body 105 and related components of the plasma processing chamber 100 are not limited and generally may be proportionally larger than the size of the substrate 302 to be processed therein. Examples of substrate sizes include 200 mm diameter, 250 mm diameter, 300 mm diameter and 450 mm diameter, among others, such as display or solar cell substrates as well.

The chamber body 105 may support a chamber lid assembly 110 to enclose the chamber volume 101. The chamber body 105 may be fabricated from aluminum or other suitable materials. A substrate access port 113 may be formed through the sidewall 112 of the chamber body 105, facilitating the transfer of the substrate 302 into and out of the plasma processing chamber 100. The access port 113 may be coupled with a transfer chamber and/or other chambers of a substrate processing system as previously described. A pumping port 145 may be formed through the sidewall 112 of the chamber body 105 and connected to the chamber volume 101. A pumping device may be coupled through the pumping port 145 to the chamber volume 101 to evacuate and control the pressure within the processing volume. The pumping device may include one or more pumps and throttle valves.

A gas panel 160 may be coupled by a gas line 167 with the chamber body 105 to supply process gases into the chamber volume 101. The gas panel 160 may include one or more process gas sources 161, 162, 163, 164 and may additionally include inert gases, non-reactive gases, and reactive gases, as may be utilized for any number of processes. Examples of process gases that may be provided by the gas panel 160 include, but are not limited to, hydrocarbon containing gas including methane, sulfur hexafluoride, silicon chloride, carbon tetrafluoride, hydrogen bromide, hydrocarbon containing gas, argon gas, chlorine, nitrogen, helium, or oxygen gas, as well as any number of additional materials. Additionally, process gasses may include nitrogen, chlorine, fluorine, oxygen, and hydrogen containing gases such as H₂, NH₃, H₂O, H₂O₂, NF₃, HF, F₂, CF₄, CHF₃, C₂F₆, C₂F₄, C₃F₆, C₄F₆, C₄F₈, BrF₃, ClF₃, SF₆, CH₃F, CH₂F₂, BCl₃, PF₃, PH₃, SO₂, and COS, among any number of additional precursors.

Valves 166 may control the flow of the process gases from the sources 161, 162, 163, 164 from the gas panel 160 and may be managed by a controller 165. The flow of the gases supplied to the chamber body 105 from the gas panel 160 may include combinations of the gases form one or more sources. The lid assembly 110 may include a nozzle 114. The nozzle 114 may be one or more ports for introducing the process gases from the sources 161, 162, 164, 163 of the gas panel 160 into the chamber volume 101. After the process gases are introduced into the plasma processing chamber 100, the gases may be energized to form plasma. An antenna 148, such as one or more inductor coils, may be provided adjacent to the plasma processing chamber 100. An antenna power supply 142 may power the antenna 148 through a match circuit 141 to inductively couple energy, such as RF energy, to the process gas to maintain a plasma formed from the process gas in the chamber volume 101 of the plasma processing chamber 100. Alternatively, or in addition to the antenna power supply 142, process electrodes below the substrate 302 and/or above the substrate 302 may be used to capacitively couple RF power to the process gases to maintain the plasma within the chamber volume 101. The operation of the power supply 142 may be controlled by a controller, such as controller 165, that also controls the operation of other components in the plasma processing chamber 100.

A substrate support pedestal 135 may be disposed in the chamber volume 101 to support the substrate 302 during processing. The substrate support pedestal 135 may include an electrostatic chuck 122 for holding the substrate 302 during processing. The electrostatic chuck (“ESC”) 122 may use the electrostatic attraction to hold the substrate 302 to the substrate support pedestal 135. The ESC 122 may be powered by an RF power supply 125 integrated with a match circuit 124. The ESC 122 may include an electrode 121 embedded within a dielectric body. The electrode 121 may be coupled with the RF power supply 125 and may provide a bias which attracts plasma ions, formed by the process gases in the chamber volume 101, to the ESC 122 and substrate 302 seated on the pedestal. The RF power supply 125 may cycle on and off, or pulse, during processing of the substrate 302. The ESC 122 may have an isolator 128 for the purpose of making the sidewall of the ESC 122 less attractive to the plasma to prolong the maintenance life cycle of the ESC 122. Additionally, the substrate support pedestal 135 may have a cathode liner 136 to protect the sidewalls of the substrate support pedestal 135 from the plasma gases and to extend the time between maintenance of the plasma processing chamber 100.

Electrode 121 may be coupled with a power source 150. The power source 150 may provide a chucking voltage of about 500 volts to about 15,000 volts to the electrode 121. The power source 150 may also include a system controller for controlling the operation of the electrode 121 by directing a DC current to the electrode 121 for chucking and de-chucking the substrate 302. For example, similar to the RF power supply 125, power supply 150 may provide a bias which attracts plasma ions, formed by the process gases in the chamber volume 101, to the ESC 122 and substrate 302 seated on the pedestal. The power supply 150 may cycle on and off, or pulse, during processing of the substrate 302. In embodiments, the power supply 150 may supply RF power, DC current or voltage for chucking and/or bias, or a combination thereof. In additional embodiments, multiple power supplies may be configured to supply RF power and DC current or voltage for chucking and/or bias. The ESC 122 may include heaters disposed within the pedestal and connected to a power source for heating the substrate, while a cooling base 129 supporting the ESC 122 may include conduits for circulating a heat transfer fluid to maintain a temperature of the ESC 122 and substrate 302 disposed thereon. The ESC 122 may be configured to perform in the temperature range required by the thermal budget of the device being fabricated on the substrate 302. For example, the ESC 122 may be configured to maintain the substrate 302 at a temperature of about −150° C. or lower to about 500° C. or higher depending on the process being performed.

The cooling base 129 may be provided to assist in controlling the temperature of the substrate 302. To mitigate process drift and time, the temperature of the substrate 302 may be maintained substantially constant by the cooling base 129 throughout the time the substrate 302 is in the cleaning chamber. In some embodiments, the temperature of the substrate 302 may be maintained throughout subsequent cleaning processes at temperatures between about −150° C. and about 500° C., although any temperatures may be utilized. A cover ring 130 may be disposed on the ESC 122 and along the periphery of the substrate support pedestal 135. The cover ring 130 may be configured to confine etching gases to a desired portion of the exposed top surface of the substrate 302, while shielding the top surface of the substrate support pedestal 135 from the plasma environment inside the plasma processing chamber 100. Lift pins may be selectively translated through the substrate support pedestal 135 to lift the substrate 302 above the substrate support pedestal 135 to facilitate access to the substrate 302 by a transfer robot or other suitable transfer mechanism as previously described.

The controller 165 may be utilized to control the process sequence, regulating the gas flows from the gas panel 160 into the plasma processing chamber 100, and other process parameters. Software routines, when executed by the CPU, transform the CPU into a specific purpose computer such as a controller, which may control the plasma processing chamber 100 such that the processes are performed in accordance with the present disclosure. The software routines may also be stored and/or executed by a second controller that may be associated with the plasma processing chamber 100.

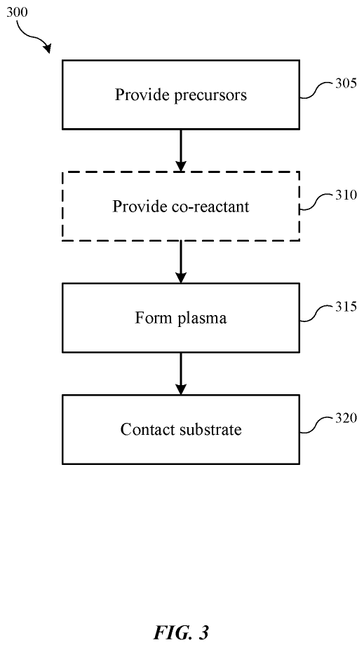

The chambers discussed previously may be used in performing exemplary methods including etching methods and treatment methods. Turning to FIG. 3 is shown exemplary operations in a method 300 according to embodiments of the present technology. Prior to the first operation of the method a substrate may be processed in one or more ways before being placed within a processing region of a chamber in which method 300 may be performed. For example, one or more layers may be formed on the substrate and then one or more patterns may be formed through a mask material. The one or more layers may include any number of silicon-containing materials. In embodiments the one or more layers may include alternating layers of silicon-and-oxygen-containing material and polysilicon material. Although the remaining disclosure will discuss silicon-and-oxygen-containing material and polysilicon material, any other known materials used in these two layers may be substituted for one or more of the layers. Some or all of these operations may be performed in chambers or system tools as previously described, or may be performed in different chambers on the same system tool, which may include the chamber in which the operations of method 300 are performed.

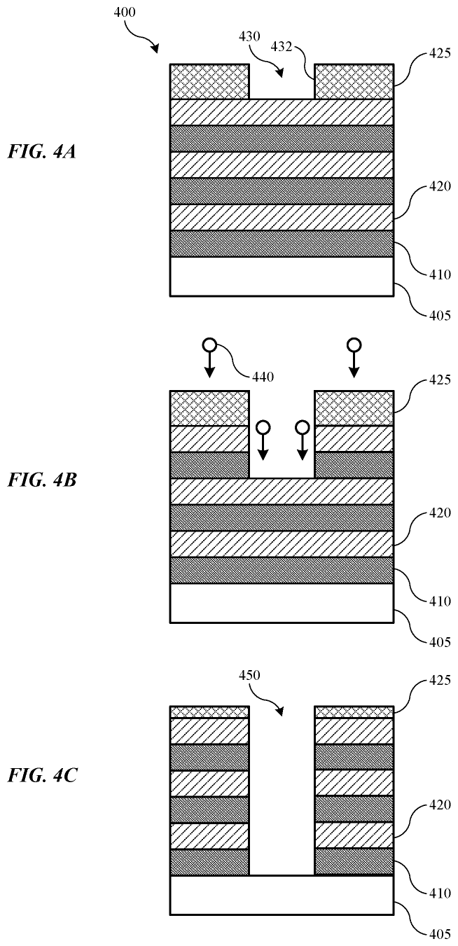

Method 300 may include a number of optional operations, which may or may not be specifically associated with some embodiments of methods according to the present technology. For example, many of the operations are described in order to provide a broader scope of the structural formation, but are not critical to the technology, or may be performed by alternative methodology as will be discussed further below. Method 300 describes operations shown schematically in FIGS. 4A-4C, the illustrations of which will be described in conjunction with the operations of method 300. It is to be understood that FIGS. 4A-4C illustrate only partial schematic views, and a substrate may contain any number of structural sections having aspects as illustrated in the figures, as well as alternative structural aspects that may still benefit from operations of the present technology.

Method 300 may or may not involve optional operations to develop the semiconductor structure to a particular fabrication operation. It is to be understood that method 300 may be performed on any number of semiconductor structures, and FIG. 4A illustrates one exemplary memory structure within which a contact cleaning or etching process may be performed. As illustrated in FIG. 4A, a processed semiconductor structure 400 may include a substrate 405, which may have a plurality of stacked layers overlying the substrate, which may be a silicon-containing material, such as polysilicon, silicon germanium, or other substrate materials, and which may be conductors for contacts with subsequent metallization. As just one non-limiting example, the layers may include a first silicon-containing material 410, which may be silicon oxide, in alternating layers with a second silicon-containing material 420, which may be silicon nitride. Although illustrated with only six layers of material, exemplary structures may include any number of layers previously discussed, which can include dozens or hundreds of layers, and it is to be understood that the figures are only schematics to illustrate aspects of the present technology. For example, the one or more layers of silicon-containing material, including the first silicon-containing material 410 and the second silicon-containing material 420, may include greater than or about 15 alternating layers material, such as greater than or about 20, greater than or about 25, greater than or about 30, greater than or about 35, greater than or about 40, greater than or about 45, greater than or about 50, greater than or about 75, greater than or about 100, or more.

A mask material 425 may be formed overlying the alternating layers, and may also be a silicon-containing material, such as any of the materials noted above, or a dielectric material such as silicon oxide, or a carbon-containing material that may be formed over the layers to protect the structure during the etching operation. The mask material 425 may be patterned to form an aperture 430 through the mask material 425. Aperture 430 may be defined by sidewalls 432 that may be composed of the mask material 425. It is to be understood that the noted structure is not intended to be limiting, and any of a variety of other semiconductor structures are similarly encompassed. Other exemplary structures may include two-dimensional and three-dimensional structures common in semiconductor manufacturing, and within which a silicon-containing material is to be removed relative to one or more other materials. Additionally, although a high-aspect-ratio structure may benefit from the present technology, the technology may be equally applicable to lower aspect ratios and any other structures.

For example, structures according to the present technology may be characterized by any aspect ratios or the height-to-width ratio of the structure, although in some embodiments the materials may be characterized by larger aspect ratios, which may not allow sufficient etching utilizing conventional technology or methodology. For example, in some embodiments the aspect ratio of exemplary structures, such as the depth of aperture 430 relative to the cross-sectional diameter, may be greater than or about 10:1, greater than or about 20:1, greater than or about 30:1, greater than or about 40:1, greater than or about 50:1, or greater. These high aspect ratios may frustrate many conventional etching operations, which may cause increased etching at higher regions of the structure due to greater interactions with etchant materials. This may detrimentally modify the structure creating sloped sidewalls within the feature due to over etching performed higher in the structure, or may greatly reduce layers such as mask material 425.

As shown in the figures, multiple materials may be present and exposed to etchant materials. The method 300 may be performed to etch or remove a portion of the first silicon-containing material 410 and the second silicon-containing material 420 exposed within the aperture 430, while minimizing etching of other materials, such as the overlying mask material 425. By utilizing processing conditions (e.g., temperature) and precursors according to embodiments of the present technology, etch rates of the first silicon-containing material 410 and the second silicon-containing material 420 may be increased. Etch rate slowdown, bowing, bending, twisting, clogging, and reduced etch rates may be reduced and/or avoided due to the present technology.

Method 300 may include providing precursors into a processing region at operation 305. The processing region may house a substrate, such as processed semiconductor structure 400, which may have one or more layers of silicon-containing material, such as first silicon-containing material 410 and second silicon-containing material 420 on substrate 405, for example. The first silicon-containing material 410 and second silicon-containing material 420 may be exposed within an opening in a mask material, such as aperture 430 in mask material 425. The precursors may include a hydrogen-containing precursor and a fluorine-containing precursor. In embodiments, a carbon-containing precursor may also be provided to the processing region of the semiconductor processing chamber, and may be provided on an intermittent basis. Further, a one or more co-reactants may be provided with the hydrogen-containing precursor, the fluorine-containing precursor, and, if present, the carbon-containing precursor at optional operation 310. The co-reactant may include a boron-containing precursor, a phosphorous-containing precursor, or a sulfur-containing precursor. Plasma effluents may be formed, such as within the processing region of the semiconductor processing chamber, at operation 315. The plasma effluents may include plasma effluents of any of the precursors previously discussed. Operations 305-315 may occur in a variety of orders, and may be performed substantially simultaneously in some embodiments. Additionally, the plasma may be formed initially from either precursor or from one or more inert precursors prior to addition of the precursors previously discussed in different embodiments.

Semiconductor structure 400 and substrate 405 may be contacted with the plasma effluents at operation 320, which may perform an etch or removal of the first silicon-containing material 410 and second silicon-containing material 420 to form a feature 450 through the materials. As illustrated in FIG. 4B, plasma effluents 440 may contact the semiconductor structure 400, and may contact all exposed surfaces, including surfaces to be etched, such as substrate 405 and substrate 405, as well as surfaces to be maintained, such as mask material 425. Because of the precursors and processing conditions associated with etching high aspect ratio features 450, conventional technologies often suffer from etch rate slowdown as aspect ratio increases, bowing and other profile issues (e.g., bending and/or twisting) due to sidewall attack, etch stop or clogging at the bottom of the feature 450, and/or imbalance of etching between oxide and nitride etch rates. However, by providing the precursors and by operating at processing conditions described in the present embodiments, the issues common in previous technologies may be reduced and/or avoided.

Precursors used in the etching processes may include a hydrogen-containing precursor as well as a fluorine-containing precursor as previously described. An exemplary hydrogen-containing precursor may be diatomic hydrogen (H₂), which may be provided to the processing region. Other sources of hydrogen may be used in conjunction with or as replacements for the H₂. For example, the hydrogen-containing precursor may include one or more materials including a hydrocarbon (CₓH_{y}), ammonia (NH₃), water (H₂O), hydrogen peroxide (H₂O₂), or additional hydrogen-containing materials. An exemplary fluorine-containing precursor may be nitrogen trifluoride (NF₃), which may be provided to the processing region. Other sources of fluorine may be used in conjunction with or as replacements for the NF₃. For example, the fluorine-containing precursor may include one or more materials including NF₃, hydrogen fluoride (HF), diatomic fluorine (F₂), carbon tetrafluoride (CF₄), trifluoromethane (CHF₃), hexafluoroethane (C₂F₆), hexafluoropropylene (C₃F₆), bromine trifluoride (BrF₃), chlorine trifluoride (ClF₃), sulfur hexafluoride (SF₆), or additional fluorine-substituted hydrocarbons, or fluorine-containing materials.

The use of both the hydrogen-containing precursor and the fluorine-containing precursor may replace the use of a more conventional etching precursor such as HF. The use of HF may result in imbalanced etch rates between the first silicon-containing material 410 and the second silicon-containing material 420. By utilizing both the hydrogen-containing precursor and the fluorine-containing precursor, an intermediate compound or molecule may be formed as a result of the interaction between the hydrogen-containing precursor and the fluorine-containing precursor. The intermediate compound or molecule, such as HF, may catalyze the reaction to accelerate the etching without directly providing HF to the processing region. Thus, the formation of the intermediate compound or molecule may reduce or eliminate any imbalance in etch rate of the first silicon-containing material 410 and the second silicon-containing material 420.

An exemplary carbon-containing precursor, if present, may include a hydrocarbon (CₓH_{y}) or a hydrofluorocarbon (CₓH_{y}F_{z}), such as methyl fluoride (CH₃F), difluoromethane (CH₂F₂), or any other carbon-containing material. Due to the nature of plasma etching, the mask material 425 may be susceptible to etching, even at reduced rates relative to the first silicon-containing material 410 and/or the second silicon-containing material 420. However, when the carbon-containing precursor is provided, the local plasma may deposit carbon products that may protect the mask material 425 as well as sidewalls of the features 450 being etched through the first silicon-containing material 410 and the second silicon-containing material 420. The carbon products may preferentially deposit at the nearest exposed surfaces, which may include mask material 425, and may have limited coverage in distal locations, such as at etch fronts nearer the substrate 405, which may be more than a micron away from the plasma formation location. Accordingly, directional etching of first silicon-containing material 410 and the second silicon-containing material 420 may not be impacted, or may be impacted in limited fashion, while etching of the mask material 425 and/or outward etching of the first silicon-containing material 410 and the second silicon-containing material 420 may be substantially or essentially prevented.

Exemplary co-reactants, such as a boron-containing precursor, a phosphorous-containing precursor, or a sulfur-containing precursor, may be provided to increase the etch rate of the second silicon-containing material 420. With the hydrogen-containing precursor and the fluorine-containing precursor, the first silicon-containing material 410 may etch at a faster rate than the second silicon-containing material 420. The co-reactant may be provided to increase an etch rate of the second silicon-containing material 420 to be more similar to the etch rate of the first silicon-containing material 410. An exemplary boron-containing precursor may be boron trichloride (BCl₃). Exemplary phosphorous-containing precursors may be phosphorus trifluoride (PF₃) or phosphine (PH₃). Exemplary sulfur-containing precursors may be sulfur dioxide (SO₂) or carbonyl sulfide (COS).

The precursors may also include any number of carrier gases, which may include nitrogen, helium, argon, or other noble, inert, or useful precursors. The carrier gases may be used to dilute the precursors, which may further reduce etching rates to allow adequate diffusion through the aperture.

The plasma effluents formed from the precursors may be formed locally in the processing region or in a remote plasma system. For example, the plasma treatment may be generated by a remote plasma source (RPS), a capacitively coupled plasma (CCP), or an inductively coupled plasma (ICP) with or without one or more carrier gases such as argon (Ar), helium (He), NH₃, nitrogen (N₂), H₂, or mixtures thereof. The plasma effluents may be a low-level plasma to limit the amount of bombardment, sputtering, and surface modification. In embodiments the plasma power may be less than or about 5,000 W, less than or about 4,500 W, less than or about 4,000 W, less than or about 3,500 W, less than or about 3,000 W, less than or about 2,500 W, less than or about 2,000 W, less than or about 1,500 W, less than or about 1,000 W, less than or about 750 W, less than or about 500 W, or less, although the plasma power may also be included in ranges between any two of these stated numbers or within any smaller range encompassed by any of the stated ranges. By utilizing a low-level plasma power, the plasma effluents may be better controlled for delivery through the apertures 430 of the mask material 425, while limiting sputtering of the mask material 425 as well as other exposed surfaces. In embodiments, the plasma power may be a high frequency plasma power, such as greater than or about 13.56 MHz, such as greater than or about 20 MHz, greater than or about 22 MHz, greater than or about 24 MHz, greater than or about 26 MHz, greater than or about 28 MHz, greater than or about 30 MHz, or more, although the frequency may also be included in ranges between any two of these stated numbers or within any smaller range encompassed by any of the stated ranges.

Additionally, a bias power may be applied to the substrate 405. The bias power may provide directional flow of plasma effluents to the substrate 405. Thus, the etchants may be directed into the apertures 435, which may facilitate the plasma effluents to progress through the materials being etch and reach the substrate 405. In embodiments, the plasma power may be greater than or about 500 V, and may be greater than or about 750 V, greater than or about 1,000 V, greater than or about 1,500 V, greater than or about 2,000 V, greater than or about 2,500 V, greater than or about 2,750 V, greater than or about 3,000 V, greater than or about 3,250 V, greater than or about 3,500 V, greater than or about 4,000 V, greater than or about 4,500 V, greater than or about 5,000 V, or more, although the bias power may also be included in ranges between any two of these stated numbers or within any smaller range encompassed by any of the stated ranges. By applying a bias power, narrow ion angle distribution may result and provide better profile control (e.g., without bending and/or twisting) and verticality of the etching. The narrow ion angle distribution may reduce sidewall attack, increase the etch rate, and make the etch front more square.

In embodiments, the bias power may be applied via an RF power supply, such as RF power supply 125, and/or a power supply used for directing DC current or voltage to the ESC, such as power supply 150. As previously discussed with regard to FIG. 2, the RF power supply and/or the power supply used for directing DC current or voltage may cycle on and off, or pulse, during processing. By pulsing, ion energy and ion flux may be better controlled and lower angular spread of the plasma effluents may be achieved. Additionally, the pulsing may neutralize a charge of the plasma effluents at the etch front, which may increase uniformity of the etch. In embodiments where the bias power is applied by both the RF power supply and the power supply used for directing DC current or voltage to the ESC, the power supplies may be synchronized or non-synchronized. The DC current or voltage may be pulsed at the micro-second scale and may be characterized by duty cycle between 0% and 100%. In some embodiments, an additional electrode may be present in the ESC for the pulsed DC current or voltage, whereas other embodiments may utilize the same electrode for both chucking and pulsing.

The precursors and processing conditions of the present technology may provide an increased etch rate of the silicon-containing materials compared to conventional technologies. In embodiments, the contacting may etch the portion of the one or more layers of silicon-containing material, such as the first silicon-containing material 410 and the second silicon-containing material 420, at an etch rate of greater than or about 200 nm/min, such as greater than or about 300 nm/min, greater than or about 400 nm/min, greater than or about 500 nm/min, greater than or about 550 nm/min, greater than or about 600 nm/min, greater than or about 650 nm/min, greater than or about 700 nm/min, greater than or about 750 nm/min, greater than or about 800 nm/min, or more, although the etch rate may also be included in ranges between any two of these stated numbers or within any smaller range encompassed by any of the stated ranges.

As illustrated in FIG. 4C, the resultant feature 450 may extend through each layer of the first silicon-containing material 410 and the second silicon-containing material 420. While the aspect ratio and depth of the etched feature 450 may depend on the number of layers of material and the thicknesses thereof, the feature 450 may be characterized by an aspect ratio, or height to width measured from an upper surface of the substrate 405 to an upper surface of the last silicon-containing material, of greater than or about 10:1. In embodiments, the feature 450 may be characterized by an aspect ratio of greater than or about 15:1, greater than or about 20:1, greater than or about 25:1, greater than or about 30:1, greater than or about 35:1, greater than or about 40:1, greater than or about 45:1, greater than or about 50:1, greater than or about 60:1, greater than or about 70:1, greater than or about 80:1, greater than or about 90:1, greater than or about 100:1, or more, although the aspect ratio may also be included in ranges between any two of these stated numbers or within any smaller range encompassed by any of the stated ranges. Additionally, a depth of the feature 450, measured from an upper surface of the substrate 405 to an upper surface of the last silicon-containing material, either the first silicon-containing material 410 or the second silicon-containing material 420, may be greater than or about 50 nm, and may be greater than or about 100 nm, greater than or about 200 nm, greater than or about 300 nm, greater than or about 400 nm, greater than or about 500 nm, greater than or about 750 nm, greater than or about 1,000 nm, or more, although the depth may also be included in ranges between any two of these stated numbers or within any smaller range encompassed by any of the stated ranges.

Process conditions may also impact the operations performed in method 300. Each of the operations of method 300 may be performed during a constant temperature in embodiments, while in some embodiments the temperature may be adjusted during different operations. For example, the substrate, pedestal, or chamber temperature during the method 300 may be maintained at a temperature less than or about 100° C., less than or about 80° C., less than or about 60° C., less than or about 40° C., less than or about 20° C., less than or about 0° C., and in some embodiments the temperature may be maintained less than or about −20° C., less than or about −40° C., less than or about −50° C., less than or about −60° C., less than or about −70° C., less than or about −80° C., less than or about −90° C., less than or about −100° C., less than or about-110° C., less than or about −120° C., or less, although the temperature may also be included in ranges between any two of these stated numbers or within any smaller range encompassed by any of the stated ranges. Maintaining the processing method, chamber, or substrate temperature at a lower relative temperature may balance the etch rate of the first silicon-containing material 410 and the second silicon-containing material 420. Additionally, the lower relative temperature in conjunction with the precursors and formation of the intermediate compound to serve as a catalyst may increase the overall etch rate of the first silicon-containing material 410 and/or the second silicon-containing material 420. Additionally, maintaining the temperature at within the previously described ranges may form an intermediate compound or molecule from the precursors that may serve as a catalyst to accelerate the etching reaction. For example, H₂ and NF₃ may form HF at a temperature less than or about 100° C. or any other previously described range that may catalyze the etch of the first silicon-containing material 410 and/or the second silicon-containing material 420.

The pressure within the processing chamber may be controlled during method 300. For example, while forming the plasma effluents and performing the removal operation, the pressure within the semiconductor processing chamber may be maintained below or about 5 Torr. Additionally, in embodiments, the pressure within the semiconductor processing chamber may be maintained below or about 4 Torr, below or about 3 Torr, below or about 2 Torr, below or about 1 Torr, below or about 500 mTorr, below or about 250 mTorr, below or about 200 mTorr, below or about 150 mTorr, below or about 100 mTorr, below or about 80 mTorr, below or about 60 mTorr, below or about 50 mTorr, below or about 45 mTorr, below or about 40 mTorr, below or about 35 mTorr, below or about 30 mTorr, below or about 25 mTorr, below or about 20 mTorr, below or about 15 mTorr, below or about 10 mTorr, or less, although the pressure may also be included in ranges between any two of these stated numbers or within any smaller range encompassed by any of the stated ranges. The pressure within the processing chamber may affect the capabilities of flow into the aperture. For example, as pressure increases, plasma effluents may have increased difficulty in permeating the aperture 430 and etched feature 450 to reach substrate 405. Accordingly, in some embodiments the pressure may be maintained below or about 1 Torr to allow effluent flow into the aperture 430 and the feature 450 being etched through the first silicon-containing material 410 and second silicon-containing material 420 on the substrate 405.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
providing a hydrogen-containing precursor and a fluorine-containing precursor to a processing region of a semiconductor processing chamber, wherein a substrate is disposed on a substrate support within the processing region, and wherein one or more layers of silicon-containing material are disposed on the substrate;
forming plasma effluents of the hydrogen-containing precursor and the fluorine-containing precursor; and
contacting one or more layers of silicon-containing material with plasma effluents of the hydrogen-containing precursor and the fluorine-containing precursor, wherein the contacting etches a portion of the one or more layers of silicon-containing material.

2. The semiconductor processing method of claim 1, wherein the hydrogen-containing precursor comprises diatomic hydrogen (H₂).

3. The semiconductor processing method of claim 1, wherein the fluorine-containing precursor comprises hydrogen fluoride (HF) or nitrogen trifluoride (NF₃).

4. The semiconductor processing method of claim 1, wherein the one or more layers of silicon-containing material comprising alternating layers of silicon-and-oxygen-containing material and silicon-and-nitrogen-containing material.

5. The semiconductor processing method of claim 3, wherein the one or more layers of silicon-containing material comprise greater than or about 20 alternating layers of silicon-and-oxygen-containing material and silicon-and-nitrogen-containing material.

6. The semiconductor processing method of claim 1, further comprising:
applying a bias power to the substrate support during the contacting.

7. The semiconductor processing method of claim 6, wherein a voltage of the bias power is greater than or about 500 V.

8. The semiconductor processing method of claim 1, wherein the contacting etches a feature in the one or more layers of silicon-containing material.

9. The semiconductor processing method of claim 8, wherein the feature is characterized by an aspect ratio of greater than or about 10:1.

10. The semiconductor processing method of claim 1, wherein the substrate is characterized by a temperature of less than or about 100° C.

11. The semiconductor processing method of claim 1, wherein the contacting etches the portion of the one or more layers of silicon-containing material at an etch rate of greater than or about 200 nm/min.

12. The semiconductor processing method of claim 1, further comprising:
providing a co-reactant with the hydrogen-containing precursor and the fluorine-containing precursor, wherein the co-reactant comprises a boron-containing precursor, a phosphorous-containing precursor, or a sulfur-containing precursor.

13. A semiconductor processing method comprising:
providing a hydrogen-containing precursor and a fluorine-containing precursor to a processing region of a semiconductor processing chamber, wherein a substrate is disposed on a substrate support within the processing region, and wherein alternating layers of silicon-and-oxygen-containing material and silicon-and-nitrogen-containing material are disposed on the substrate;
forming plasma effluents of the hydrogen-containing precursor and the fluorine-containing precursor; and
contacting one or more layers of silicon-containing material with plasma effluents of the hydrogen-containing precursor and the fluorine-containing precursor, wherein the contacting etches a feature through the alternating layers of silicon-and-oxygen-containing material and silicon-and-nitrogen-containing material.

14. The semiconductor processing method of claim 13, further comprising:
providing a co-reactant with the hydrogen-containing precursor and the fluorine-containing precursor, wherein the co-reactant comprises a boron-containing precursor, a phosphorous-containing precursor, or a sulfur-containing precursor.

15. The semiconductor processing method of claim 13, wherein the contacting etches the alternating layers of silicon-and-oxygen-containing material and silicon-and-nitrogen-containing material at an etch rate of greater than or about 500 nm/min.

16. The semiconductor processing method of claim 13, wherein a pressure within the semiconductor processing chamber is maintained at less than or about 150 mTorr.

17. The semiconductor processing method of claim 13, wherein the plasma effluents of the hydrogen-containing precursor and the fluorine-containing precursor are generated at a plasma power of less than or about 5,000 W.

18. A semiconductor processing method comprising:
providing a hydrogen-containing precursor and a fluorine-containing precursor to a processing region of a semiconductor processing chamber, wherein a substrate is disposed on a substrate support within the processing region, and wherein alternating layers of silicon-and-oxygen-containing material and silicon-and-nitrogen-containing material are disposed on the substrate;
providing a co-reactant with the hydrogen-containing precursor and the fluorine-containing precursor;
forming plasma effluents of the hydrogen-containing precursor, the fluorine-containing precursor, and the co-reactant;
contacting one or more layers of silicon-containing material with plasma effluents of the hydrogen-containing precursor, the fluorine-containing precursor, and the co-reactant, wherein the contacting etches a feature through the alternating layers of silicon-and-oxygen-containing material and silicon-and-nitrogen-containing material; and
applying a bias power to the substrate support during the contacting, wherein the bias power draws the plasma effluents of the hydrogen-containing precursor, the fluorine-containing precursor, and the co-reactant to the substrate resulting in an anisotropic etch.

19. The semiconductor processing method of claim 18, wherein the co-reactant comprises a phosphorous-containing precursor.

20. The semiconductor processing method of claim 18, wherein the substrate is characterized by a temperature of less than or about 0° C.
